(19) United States
(12) Patent Application Publication
(10) Pub. No.: US 2013/0257239 A1
(43) Pub. Date: Oct. 3, 2013

(54) Middle Frame for LCD Device and LCD Device

(71) Applicants: Yicheng Kuo, Shenzhen (CN); Shihhsiang Chen, Shenzhen (CN); Gege Zhou, Shenzhen (CN)

(72) Inventors: Yicheng Kuo, Shenzhen (CN); Shihhsiang Chen, Shenzhen (CN); Gege Zhou, Shenzhen (CN)

(21) Appl. No.: 13/505,505

(22) PCT Filed: Apr. 6, 2012
(86) PCT No.: PCT/CN12/73608

§ 371 Date: May 2, 2012

(30) Foreign Application Priority Data
Apr. 1, 2012 (CN) 201210096055.8

(51) Int. Cl. G02F 1/1333; H05K 5/02

(52) U.S. Cl. 312/223.1

(57) ABSTRACT

The invention relates to the field of LCDs, and more particularly to a middle frame for an LCD device and an LCD device. The middle frame is of a separated structure, and includes a plurality of frame members. The inner surface at the corner of said frame member(s) is provided with reinforcing ribs. The middle frame for an LCD device of the invention is of a separated structure. The inner surface at the corner of the frame member(s) of the middle frame is provided with reinforcing rib(s). The reinforcing rib(s) can improve the strength of the middle frame, and the frame members with the same cross section can be joined to form middle frame(s) which has a larger size and meets the strength requirement.

### TECHNICAL FIELD

The invention relates to the field of liquid crystal displays (LCDs), and more particularly to a middle frame for an LCD device and an LCD device.

### BACKGROUND

A conventional LCD device generally includes a front frame, an LCD panel, a middle frame, a backlight module, a back cover and the like. The middle frame is generally made of plastic material and formed using integrated injection mold, having a high strength. However, because LCD devices have different sizes, special molds have to be developed for various middle frames. Because the special molds have a high manufacturing cost and long manufacturing cycle, the production cost of the middle frames is very high, and the whole development cycle of LCD devices is also affected.

### SUMMARY

In view of the above-described problems, the aim of the invention is to provide a high-strength separated backlight module for an LCD device and an LCD device comprising the middle frame.

A technical scheme of the invention is that: a middle frame for an LCD device, the middle frame is of a separated structure, and comprises a plurality of frame members; the inner surface at the corner of the frame member(s) is provided with reinforcing ribs, the reinforcing ribs are arranged at both ends of each frame member, the number of the reinforcing ribs is multiple, and the reinforcing ribs are uniformly distributed on the frame members. The frame member comprises a horizontal edge and a vertical edge. The reinforcing ribs are triangular or right trapezoid in shape, one side of each reinforcing rib is in contact with the vertical edge, and the other side is in contact with the horizontal edge. The thickness of each reinforcing rib is 0.6-0.8 times the wall thickness of the middle frame.

Another technical scheme of the invention is that: a middle frame for an LCD device, the middle frame is of a separated structure, and comprises a plurality of frame members; the inner surface at the corner of the frame member(s) is provided with reinforcing rib(s).

Preferably, the reinforcing ribs are arranged at both ends of the frame member(s). Because every two frame members are connected in general, the reinforcing ribs are positioned at the joints of the middle frame. Thus, the joint strength of the middle frame is increased, and the strength of the weak part(s) of the middle frame is improved.

Preferably, the number of the reinforcing ribs is multiple, and the reinforcing ribs are uniformly distributed on the frame members. Thus, the overall strength of the frame members becomes better.

Preferably, the frame member comprises a horizontal edge and a vertical edge. The reinforcing ribs are triangular or right trapezoid in shape, one side of each reinforcing rib is in contact with the vertical edge, and the other side is in contact with the horizontal edge.

Preferably, the thickness of each reinforcing rib is 0.6-0.8 times the wall thickness of the middle frame, thereby preventing the frame members from generating obvious contraction during production.

The invention further provides a technical scheme: an LCD device comprises a front frame, a middle frame, and a back cover; the middle frame is of a separated structure, and comprises a plurality of frame members; the inner surface at the corner of the frame member(s) is provided with reinforcing rib(s).

Preferably, the reinforcing ribs are arranged at both ends of the frame member.

Preferably, the number of the reinforcing ribs is multiple, and the reinforcing ribs are uniformly distributed on the frame members.

Preferably, the upper end of the side of the back cover is bent inwards, and the bent back cover has higher strength to better play a role of structure support.

Preferably, the side of the back cover is positioned inside the side of the middle frame, and the upper end of the side of the back cover is bent inwards, to avoid the reinforcing ribs on the middle frame to prevent mutual interference between the two during assembly.

Advantages of the invention are summarized below: the middle frame for an LCD device of the invention is of a separated structure, namely the middle frame comprises a plurality of frame members. The plurality of frame members can be assembled into middle frames with different sizes. It is not necessary to make special molds for various middle frames. Thus, the cost is reduced, and the development cycle is shortened. However, the strength of the separated middle frame is weak, especially at the joints of the frame members. The larger the middle frame is, the more the frame members is, the more the joints is, and the weaker the strength of the middle frame is, thereby being difficult to meet the design requirement. The inner surface at the corner of the frame member(s) of the middle frame is provided with reinforcing rib(s). The reinforcing rib(s) can improve the strength of the middle frame, and the frame members with the same cross section can be joined to form middle frame(s) which has a larger size and meets the strength requirement.

### BRIEF DESCRIPTION OF FIGURES

FIG. 1 is a structure diagram of an LCD device according to an example of the invention;

FIG. 2 is a structure diagram of a middle frame for an LCD device according to an example of the invention; and

FIG. 3 is a structure diagram of a middle frame for an LCD device according to another example of the invention.

Legends: 1. front frame; 2; middle frame; 21. frame member; 22. reinforcing rib; 3. back cover.

### DETAILED DESCRIPTION

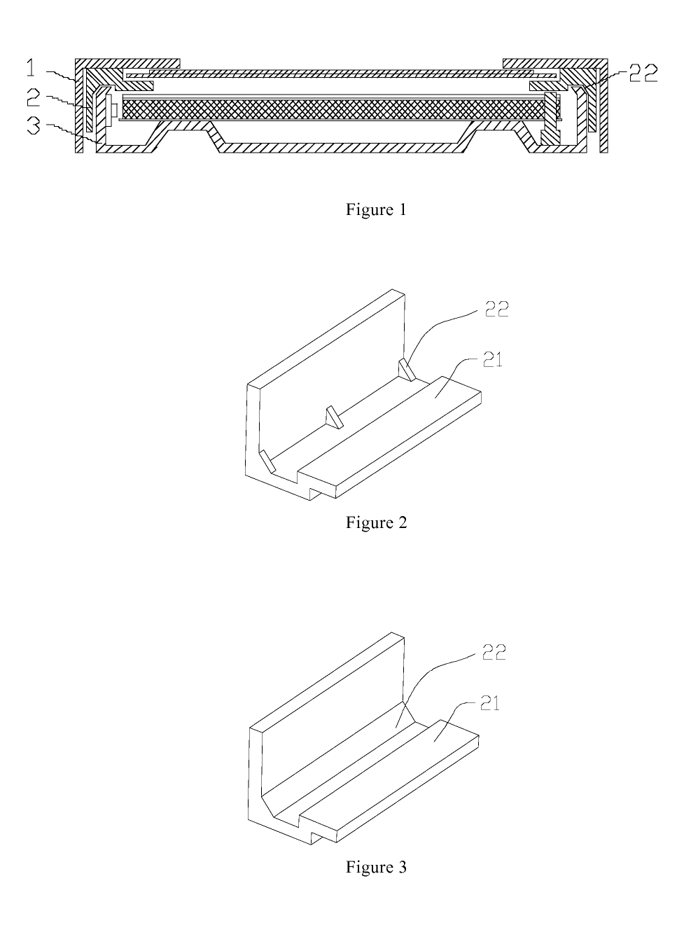

The invention provides an LCD device. FIG. 1 and FIG. 2 show an example of the LCD device. The LCD device comprises a front frame 1, a middle frame 2, and a back cover 3. The middle frame 2 is of a separated structure, and comprises a plurality of frame members 21. The inner surface at the corner of the frame member(s) 21 is provided with reinforcing rib(s) 22. The frame member 21 comprises a horizontal edge and a vertical edge; one side of each reinforcing rib 22 is in contact with the vertical edge, and the other side is in contact with the horizontal edge. In the example, the reinforcing rib(s) 22 is triangular in shape. The reinforcing rib(s) in right trapezoid shape can also be used in accordance with actual demands. Preferably, the thickness of the reinforcing rib 22 is 0.6-0.8 times the wall thickness of the middle frame 2, thereby preventing the frame members 21 from generating obvious contraction during production.

The middle frame 2 for an LCD device of the invention is of a separated structure, namely a plurality of frame members 21 are assembled to form the middle frame. The plurality of frame members 21 can be assembled into middle frames with different sizes. It is not necessary to make special molds for various middle frames. Thus, the cost is reduced, and the development cycle is shortened. However, the strength of the separated middle frame is weak, especially at the joints of the frame members. The larger the middle frames is, the more the frame members is, the more the joints is, and the weaker the strength of the middle frame is, thereby being difficult to meet design requirements. The inner surface at the corner of the frame member(s) 21 is provided with reinforcing rib(s) 22. The reinforcing rib(s) 22 can improve the strength of the middle frame 2, and the frame members 21 with the same cross section can be joined to form middle frame(s) 2 which has a larger size and meets the strength requirement.

In the example, the reinforcing ribs 22 are arranged at both ends of each frame member 21. Because every two frame members 21 are connected in general, the reinforcing ribs 22 are positioned at the joint of the middle frame 2. As described in the background, the middle frame has the weakest strength at the joint. In the invention, the joint(s) of the middle frame 2 is provided with reinforcing rib(s) 22. Thus, the joint strength of the middle frames 2 is increased, and the strength of the weak part(s) of the middle frame 2 is improved.

If an individual frame member 21 is long, the middle of the frame member 21 can be additionally provided with multiple reinforcing ribs 22, and the reinforcing ribs 22 are uniformly distributed on the frame member 21. Thus, the overall strength of the frame member 21 becomes better.

In the example, the upper end of the side of the back cover 3 is bent inwards, and the bent back cover has higher strength to play a role of better structure support. Because the side of the back cover 3 of the example is positioned inside the side of the middle frame 2, the upper end of the side of the back cover 3 is bent inwards, the bent back cover 3 further plays a role of avoiding the reinforcing rib(s) 22 on the middle frame 2 to prevent mutual interference between the two during assembly.

FIG. 3 shows another example of the middle frame for an LCD device of the invention. The reinforcing rib 22 integratedly penetrates through the whole frame member 21, to enable the strength of the frame member 21 to be improved in the whole length direction. Because other structures and advantages coincide with those of the aforementioned example, the second example will not give unnecessary details.

The invention is described in detail in accordance with the above contents with the specific preferred examples. However, this invention is not limited to the specific examples. For the ordinary technical personnel of the technical field of the invention, on the premise of keeping the conception of the invention, the technical personnel can also make simple deductions or replacements, and all of which should be considered to belong to the protection scope of the invention.

We claim:

1. A middle frame for an LCD device, wherein said middle frame is of a separated structure, and comprises a plurality of frame members; the inner surface at the corner of said frame member(s) is provided with reinforcing ribs, said reinforcing ribs are arranged at both ends of said frame member, the number of said reinforcing ribs is multiple, and said reinforcing ribs are uniformly distributed on said frame members; said frame member comprises a horizontal edge and a vertical edge; said reinforcing ribs are triangular or right trapezoid in shape, one side of each reinforcing rib is in contact with said vertical edge, and the other side is in contact with said horizontal edge; the thickness of said reinforcing ribs is 0.6-0.8 times the wall thickness of said middle frame.

2. A middle frame for an LCD device, wherein said middle frame is of a separated structure, and comprises a plurality of frame members; the inner surface at the corner of said frame member(s) is provided with reinforcing rib(s.)

3. The middle frame for an LCD device of claim 2, wherein said reinforcing ribs are arranged at both ends of said frame member.

4. The middle frame for an LCD device of claim 3, wherein the number of said reinforcing ribs is multiple, and said reinforcing ribs are uniformly distributed on the frame members.

5. The middle frame for an LCD device of claim 4, wherein said frame member comprises a horizontal edge and a vertical edge; said reinforcing ribs are triangular or right trapezoid in shape, one side of each reinforcing rib is in contact with said vertical edge, and the other side is in contact with said horizontal edge.

6. The middle frame for an LCD device of claim 4, wherein the thickness of said reinforcing ribs is 0.6-0.8 times the wall thickness of said middle frame.

7. An LCD device, comprising: a front frame, a middle frame, and a back cover; wherein said middle frame is of a separated structure, and comprises a plurality of frame members; the inner surface at the corner of the frame member(s) is provided with reinforcing rib(s.)

8. The LCD device of claim 7, wherein said reinforcing ribs are arranged at both ends of said frame member.

9. The LCD device of claim 8, wherein the number of said reinforcing ribs is multiple, and said reinforcing ribs are uniformly distributed on said frame members.

10. The LCD device of claim 7, wherein the upper end of the side of said back cover is bent inwards.

11. The LCD device of claim 8, wherein the upper end of the side of said back cover is bent inwards.

12. The LCD device of claim 9, wherein the upper end of the side of said back cover is bent inwards.

13. The LCD device of claim 7, wherein the side of said back cover is positioned inside the side of said middle frame, and the upper end of the side of said back cover is bent inwards, to avoid the reinforcing rib(s) on said middle frame.

14. The LCD device of claim 8, wherein the side of said back cover is positioned inside the side of said middle frame, and the upper end of the side of said back cover is bent inwards, to avoid the reinforcing ribs on said middle frame.

15. The LCD device of claim 9, wherein the side of said back cover is positioned inside the side of said middle frame, and the upper end of the side of said back cover is bent inwards, to avoid the reinforcing ribs on said middle frame.
